(19) United States
(12) Patent Application Publication
(10) Pub. No.: US 2006/0011325 A1
(43) Pub. Date: Jan. 19, 2006

(54) Micro-channel heat sink

(76) Inventor: Daniel Jon Schlitz, Lilburn, GA (US)

Correspondence Address: PILLSBURY WINTHROP SHAW PITTMAN LLP, P.O. BOX 10500, MCLEAN, VA, 22102, US

(21) Appl. No.: 11/181,106

(22) Filed: Jul. 13, 2005

Related U.S. Application Data
(60) Provisional application No. 60/588,001, filed on Jul. 13, 2004.

(51) Int. Cl. H05K 7/20

(52) U.S. Cl. 165/80.3; 361/704

(57) ABSTRACT

A heat sink with an arrangement of a plurality of micro-fins, spaced apart to form microchannels through which a gas can flow. The heat sink includes a conductive apparatus for conducting heat from a heat source to the arrangement of micro-fins. The conductive apparatus includes a post, with a bottom surface at a proximal end for contact with a heat source. The arrangement extends radially outward from the post at a more distal end spaced apart from the bottom surface of the post. In one embodiment, the conductive apparatus includes a plurality of ribs extending radially outward from the post. Each micro-fin has a length that bridges the space between two ribs. The micro-fins are spaced substantially parallel to each other to form micro-channels for passage of cooling gas. Another embodiment includes a plurality of micro-fins extending substantially perpendicularly outward from the post, and separated to form micro-channels. Another embodiment includes a plurality of micro-fins extending substantially perpendicular to a rectangular post. In operation, heat is conducted from the heat source, through the post to the micro-fins, and into gas around each micro-fin. A fan or other gas pump can be used to force a flow of the gas through the micro-channels and thereby through the arrangement.

### CROSS-REFERENCE TO RELATED APPLICATIONS

The present application is based on, and claims priority from, U.S. Provisional Patent Appln. No. 60/588,001 filed Jul. 13, 2004, the contents of which are incorporated herein by reference in their entirety.

### FIELD OF THE INVENTION

The present invention relates generally to cooling of electronic components, and more particularly to heat sinks with air cooled fins for cooling electronic components such as integrated circuits.

### BACKGROUND OF THE INVENTION

It is well known that heat can be a problem in many environments, and that overheating can lead to failures of components such as integrated circuits (e.g. a central processing unit (CPU) of a computer) and other electronic components.

Heat sinks are a common device used to prevent overheating, and mainly rely on the dissipation of heat from the device using air. However, dissipating heat using a gas, such as air, is difficult because of the poor thermal conductivity of gases. Gases also have a low heat capacity, which causes them to heat up quickly, which retards the rate of heat absorption by decreasing the temperature difference between the gas and the heat sink.

Conventional heat sinks have a limited amount of surface area that can be put into a given volume, and as a result, an adequate conventional heat sink must be large in order to provide the necessary convection surface area. Generally, in heat sink designs for cooling a heat source on a substrate, the heat sink dimensions extend substantially perpendicular to the substrate and heat source. Additionally, these heat sink designs do not integrate well with certain types of fluid pump designs.

A number of U.S. patents have addressed the problem of heat exchange, including U.S. Pat. No. 6,415,860, U.S. Pat. No. 5,801,442, U.S. Pat. No. 6,712,127, U.S. Pat. No. 6,244,331, U.S. Pat. No. 6,200,536, U.S. Pat. No. 6,705,393, and U.S. Pat. No. 6,675,875. However, these references do not fully solve the problems associated with effective cooling of electronic components as described above.

Micro-channels have been described that can create very high convective heat transfer rates, even with gases. In theory, the high convection rates of micro-channels can overcome the poor thermal conductivity issue. However, there are two major obstacles to the practical implementation of a micro-channel concept in a heat sink application. First, micro-channels create a large resistance to fluid flow. The resistance increases as the length (in the direction of flow) increases. Second, the low heat capacity of gases means that they heat up quickly and become ineffective at dissipating heat.

Accordingly, it would be desirable if there was a way to overcome these and other obstacles against implementing a micro-channel concept in a heat sink application.

### SUMMARY OF THE INVENTION

An embodiment of the present invention includes a heat sink with an arrangement of micro-fins, spaced apart to form microchannels through which a gas can flow. The heat sink includes a conductive apparatus for conducting heat from a heat source to the arrangement of micro-fins. The conductive apparatus includes a post, with a bottom surface at a proximal end for contact with the heat source. The arrangement extends outward from the post at a distal end in a plane spaced apart from a plane of the bottom surface of the post. In one embodiment, the conductive apparatus includes a plurality of ribs that extend radially outward from the post. Each micro-fin has a length that bridges the space between two ribs. The micro-fins are spaced substantially parallel to each other with a space between them, forming micro-channels for passage of cooling gas. Another embodiment includes a plurality of micro-fins extending radially outward from the post, and also separated to form micro-channels. Another embodiment includes a plurality of micro-fins extending perpendicular to a rectangular post. In operation, heat is conducted from the heat source, through the post to the micro-fins, and into gas around each micro-fin. A fan or other gas pump can be used to force a flow of the gas through the micro-channels and thereby through the arrangement.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1A is a top isometric view of a first embodiment of a heat sink in accordance with the present invention;

FIG. 1B is a bottom isometric view of the first embodiment as shown in FIG. 1A;

FIG. 2 illustrates the flow of heat and gas facilitated by the heat sink of the present invention, with the gas flow passing through the micro-channels from the top of the arrangement of micro-fins to the bottom of the arrangement;

FIG. 3 illustrates the flow of heat and gas facilitated by the heat sink of the present invention, with the gas flowing through micro-channels from the bottom of the micro-fin arrangement to the top of the micro-fin arrangement;

FIG. 4 is a close up view of the micro-channels and micro-fins formed and arranged as illustrated in FIGS. 1A and 1B;

FIG. 5A illustrates gas flow through a micro-channel;

FIG. 5B illustrates a thermal resistance circuit model of the heat sink of the invention that is useful for determining optimized parameters for implementations of the heat sink;

FIG. 6 is a graph illustrating the optimization of the number of fins and ribs under one set of constraints of a heat sink in accordance with the present invention;

FIG. 7 illustrates an alternative embodiment of a heat sink in accordance with the present invention;

FIG. 8 illustrates an alternative arrangement of micro-channels and fins in accordance with additional embodiments of the present invention;

FIG. 9 illustrates an alternative arrangement of micro-channels and fins in accordance with additional embodiments of the present invention; and

FIG. 10 illustrates a further alternative arrangement of micro-channels and fins in accordance with additional embodiments of the present invention.

### DETAILED DESCRIPTION OF THE PREFERRED EMBODIMENTS

The present invention will now be described in detail with reference to the figures of the drawing, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, the present invention is to include multiple components as well as a single component when only one is shown, and vice versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

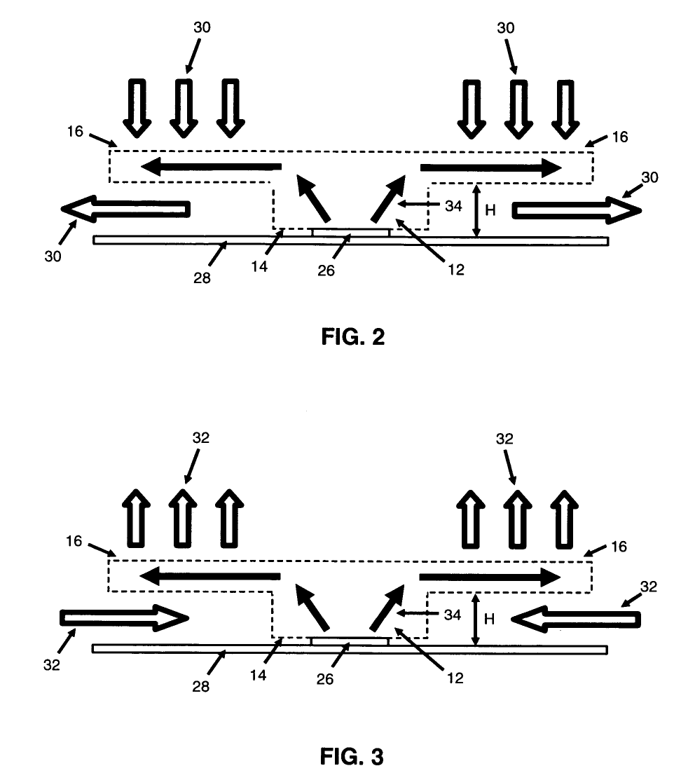

Generally, the present invention is a heat sink that utilizes an arrangement of micro-fins spaced apart to form microchannels for passage of a gas from one side of the arrangement to an opposite side of the arrangement, wherein the micro-channels create high convection coefficients at the surfaces of the micro-fins. According to a first aspect of the invention, the arrangement of micro-fins is dimensioned to be thin i.e. a small depth, which dimension is in the direction of flow of a gas passing through a micro-channel from one side of the arrangement to an opposite side. The small depth is for maintaining a large heat sink-to-gas temperature difference and for minimizing the pressure drop of gas flowing through the micro-channels. The microchannels are located in a plate-like region which is offset by a distance H from the heat source (as indicated in FIGS. 2 and 3). This allows a gas to flow through the micro-channels in a direction that is substantially perpendicular to (i.e. directly toward or away from) the substrate containing the heat source, thereby cooling the heat source. According to a further aspect of the invention, the microchannels are arranged in a substantially parallel fashion to provide a large amount of surface area in a small volume. The result is a high performance gas-cooled heat sink that is particularly well suited for cooling such prone components as personal computer CPUs and other electronic devices.

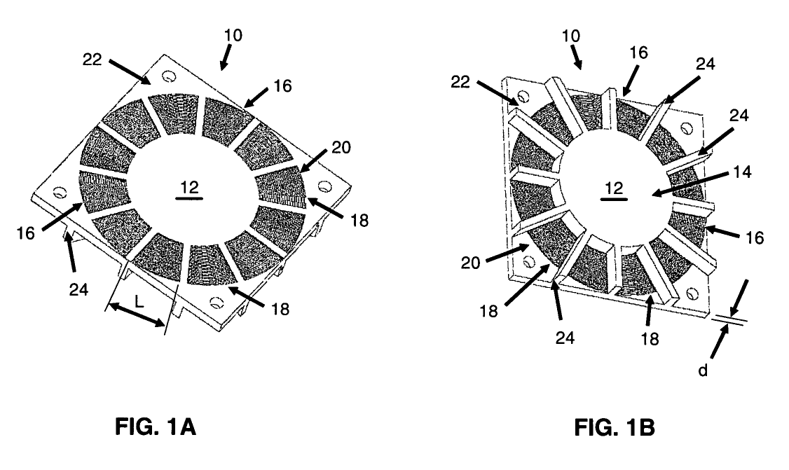

FIGS. 1A and 1B are isometric views showing primarily the top and bottom, respectively, of a first preferred embodiment of a heat sink 10 according to the present invention. As shown in FIGS. 1A and 1B, the heat sink 10 consists of a center post 12, with a bottom surface 14 (FIG. 1B) for contact with a heat source. Micro-fin arrangement portions 16 each include a plurality of micro-fins 18, spaced apart to form a plurality of micro-channels 20 i.e. the spaces between the micro-fins. The micro-fins as shown are formed in a plate-like portion 22. In one example of the present invention, the center post 12 and fins 18 are fabricated of the same material such as aluminum. However, the present invention also includes posts and fins constructed of other materials, such as copper, silicon-carbide, graphite, etc. Still further, it is not necessary for the center post and fins to be made from the same material. The micro-fins have a depth “d” equal to the thickness of the portion 22. The micro-fins 18, and therefore also the micro-channels 20 in this example have a length “L” in the planar surface.

In the embodiment of FIGS. 1A and 1B the micro-fins 18 lie substantially on arcs of respective concentric circles each with a center coinciding with the center of the post 12. Within the portions 16, therefore, the fins are substantially parallel to each other along the concentric rings. Other shapes and arrangements of the micro-fins are also included in the present invention. The micro-fins 18 extend from one rib 24 to another rib 24 so as to allow heat from a heat source to be conducted through the post and then to the ribs 24 and then to each micro-fin.

Various numbers of conducting ribs 24 and/or heat pipes may or may not be present to aid in the conductance of heat from the center post to the outer portions of the heat sink micro-fin arrangement. In other words, although the embodiment of FIGS. 1A and 1B shows ribs 24 of solid material, the ribs can also be constructed of other materials, and for example can include heat pipes. The ribs 24 can be integral with the portions 16, and can have a thickness equal to the depth “d”, or they can have a different thickness. As shown in FIGS. 1A and 1B, the ribs 24 are thicker than the micro-fins 18 of thickness “d”. The heat sink 10 parts including the post 12, fins 18 and ribs 24 can all be an integrally formed heat sink of one material, or can be formed from separate parts, each of the same or different materials. A single, integral material construction has an advantage of avoiding heat barriers due to material junctions. The ribs 24 have a larger cross section than the micro-fins, and serve the purpose of conducting heat from the post 12 to the micro-fins 18.

It should be noted that the present invention is not limited to the structure as shown in FIGS. 1A and 1B or other figures of the present specification. More generally, the present invention includes an array, arrays or arrangements of a plurality of micro-fins spaced apart to form a plurality of micro-channels providing openings through the array for passage of a cooling gas, and further includes conductive apparatus for conducting heat energy from a heat source to each micro-fin. The apparatus for conducting heat energy to the micro-fins as shown in FIGS. 1A and 1B includes the post 12 and the ribs 24. Other structures for conducting heat from a heat source to the micro-fins will be apparent to those skilled in the art upon reading the present disclosure, and these are to be included in the spirit of the present invention. Similarly, the micro-fins can be configured in various ways that will be apparent to those skilled in the art, and these are also to be included in the spirit of the present invention. In the example in FIGS. 1A and 1B wherein ribs 24 are provided, they extend radially from the center post 12.

The flow of heat and gas (e.g. air) through a heat sink according to the present invention such as that shown in FIG. 1 is shown schematically in FIGS. 2 and 3. As shown in both figures, heat flows into the center post 12 by contact with a heat source 26. For example, the heat source 26 could be an integrated circuit such as a CPU mounted on a substrate or other surface 28. Next, the heat flows from the post 12 to the micro-fins via any of various conductive structures. As shown in FIGS. 1A and 1B, the heat flows radially outward through the ribs 24 which could be of various structures such as solid metal, or heat pipes. An important and innovative feature of the embodiment shown is that the portions 16 are offset from the plane of the post bottom 14 and therefore also from a heat source 26. This allows gas (e.g. air) to freely flow in between the portions 16 and a substrate 28 on which the heat source 26 may reside. Consequently, a gas is able to flow through the micro-channels formed by the micro-fins 18 either from or to the space between the portions 16, and for example a substrate. This arrangement allows for the use of a large parallel array of channels to be contained in a short structure. In FIG. 2, the gas 30 flows toward the portions 16, through the micro-channels 20 and exhausts radially outwards from the center post 12 in the space between the portions and the substrate. FIG. 3 shows a flow of gas 32 in the opposite direction. The heat symbolically indicated by arrow 34 is optimally transferred from the heat sink 10 to the gas 30, 32 as it passes through the micro-channels 20.

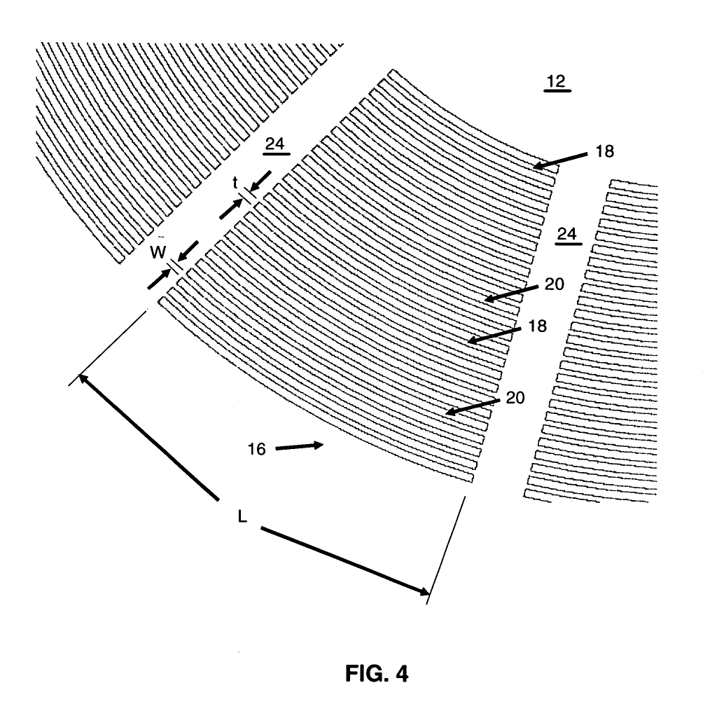

An enlargened view of the portions 16 in the embodiment of FIGS. 1A and 1B is shown in FIG. 4. Heat is conducted away from the center post 12 by the ribs 24 and is distributed to the micro-channels 20 by the micro-fins 18. Many geometrical parameters can be optimized such that the heat sink dissipates a maximum amount of heat in the smallest possible volume. The parameters include: the micro-fin length “L”, width “W”, and depth “d”; the number of micro-channels 20; the number, width and thickness of the ribs 24; and the size of the center post 12.

According to a first aspect of the present invention, the depth “d” of the micro-fins 18/micro-channels 20 is kept short to minimize the heating of the gas as it passes through, but long enough to provide ample micro-fin surface area for heat transfer to the gas. An optimal micro-fin depth “d” is found by balancing the need for a large convection surface with the desire to minimize the gas flow resistance.

According to a further aspect of the present invention, the width “W” of the micro-fins is also optimized. Reducing the width “W” of the micro-fins allows for more micro-channels, but increasing the width “W” provides for better conduction of heat to the micro-channel walls. The cross sectional area and number of ribs is also a critical parameter. A large number of wide ribs conveys heat more efficiently to the outer portions of the heat sink micro-fins; but wider ribs result in less space available for micro-channels.

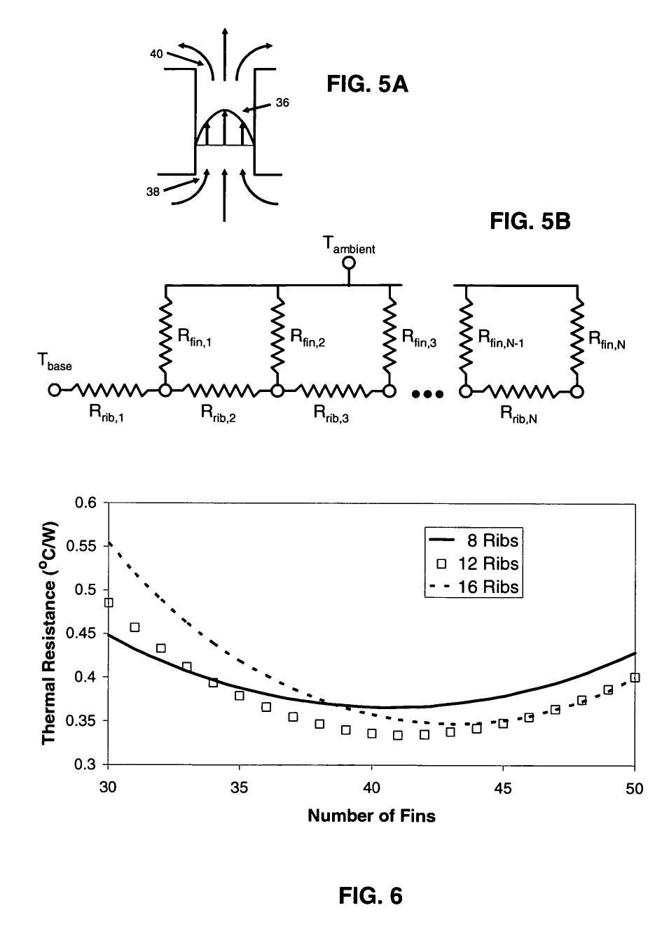

All of the parameters are interrelated and can be optimized using a mathematical model of the heat sink and optimization techniques. The gas flow can be modeled as generated by an external fan or other gas pump that can force the gas through the micro-channels. As illustrated in FIG. 5A, the total resistance to the gas flow through the micro-channel 36 comes from minor losses at the inlet 38 and outlet 40 of the microchannels and frictional losses inside the channel 36 (see R. Blevins, Applied Fluid Dynamics Handbook, Krieger, Malabar Fla., 1992, the contents of which are incorporated by reference herein) (see FIG. 5A), and is summarized according to the following formula:
ΔP_{system}=ΔP_{entrance}+ΔP_{friction}+ΔPₑₓᵢₜ (1)

Each of the terms in equation (1) is a function of the gas flow rate. The gas pump also has a relationship between flow rate and pressure drop. Stated mathematically:
ΔP_{system}=f₁(gas flow rate) and ΔPₚᵤₘₚ=f₂(gas flow rate) (2)

The system flow rate is found by equating ΔP_{system} and ΔPₚᵤₘₚ. This is the operating point of the pump and determines the system flow rate and pressure drop.

Correlations are used to determine the convection coefficient (see W. Kays and M. Crawford, Convective Heat and Mass Transfer, McGraw-Hill, New York, 1980, the contents of which are incorporated by reference herein). In general, the convection coefficient h is a function of the gas flow rate, gas properties and channel geometry and is represented mathematically as:
h=f₃(gas flow rate, gas properties, channel geometry)

The thermal conduction resistance R of a rib and a fin is modeled as (see F. Incropera and D DeWitt, Fundamentals of Heat and Mass Transfer, John Wiley & Sons, New York, 1990, the contents of which are incorporated by reference herein):
R_{rib}=length rib/k_{rib}Area_{rib}
R_{fin}=f₄(h, k_{fin}, fin geometry)

The terms k_{rib} and k_{fin} are the thermal conductivity of the rib and fin materials, respectively. As shown in FIG. 5B, the heat sink can be thermally modeled as a series-parallel arrangement of resistances of ribs and fins.

The equations given above are a system of equations that are solved to determine the overall thermal resistance of the cooling system. This model is used to determine the heat sink geometry, gas pump and heat transport parameters that optimize the cooling system for a given design condition.

In one example, the heat sink of the present invention can be used with a typical CPU. In further example, the center post and fins can be fabricated from aluminum, and the thickness of the arrangement i.e. micro-fin/micro channel depth “d” is about 100 to 10,000 microns, the length “L” of the micro-fins and microchannels is about 3 to 50 mm, the width “W” of the micro-fins is about 50 to 2000 microns, the micro-channel spacing “t” is about 100 to 2000 microns, the diameter of the center post is about 5 to 50 mm, and the height of the center post (i.e. the offset between the plate and the heat source) is about 1-10 mm.

FIG. 6 further illustrates how the number of micro-fins 18 and ribs 24 can be selected in the above implementation example. As shown in FIG. 6, for this particular set of constraints, the optimal design was found to contain approximately 41 micro-fins and 12 ribs (i.e. spokes).

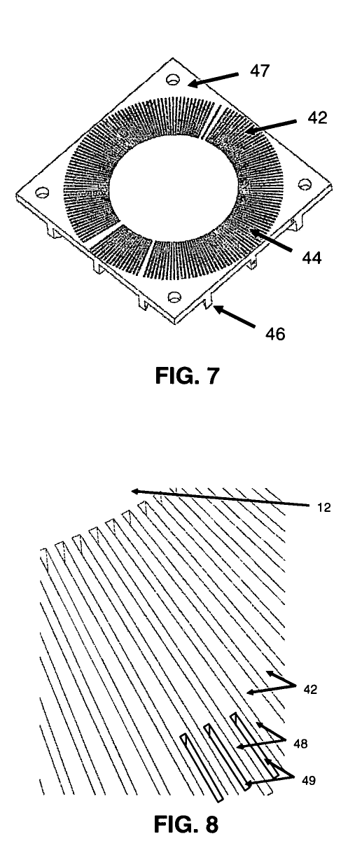

As set forth more fully above, one important aspect of the heat sink according to the present invention is an arrangement of a plurality of relatively short micro-fins and corresponding micro-channels located in portions that are offset from the heat source. It should be noted that the micro-fins and micro-channels can have many different shapes and configurations. Although FIG. 4 shows an embodiment where the micro-fins run azimuthally in concentric circumferential rings, the invention is not limited to this example. An alternative embodiment is shown in FIG. 7. In this case the micro-fins 42 and corresponding micro-channels extend radially outward from a center post 44, and can be formed in a plate-like portion 47. Ribs 46 are also shown, and are optional.

FIG. 8 is a close-up view of the fins 42 of FIG. 7 and slots/micro-channels 48 and shows a further alternative embodiment wherein shorter slots/micro-channels 49 are interspersed in between longer slots/micro-channels.

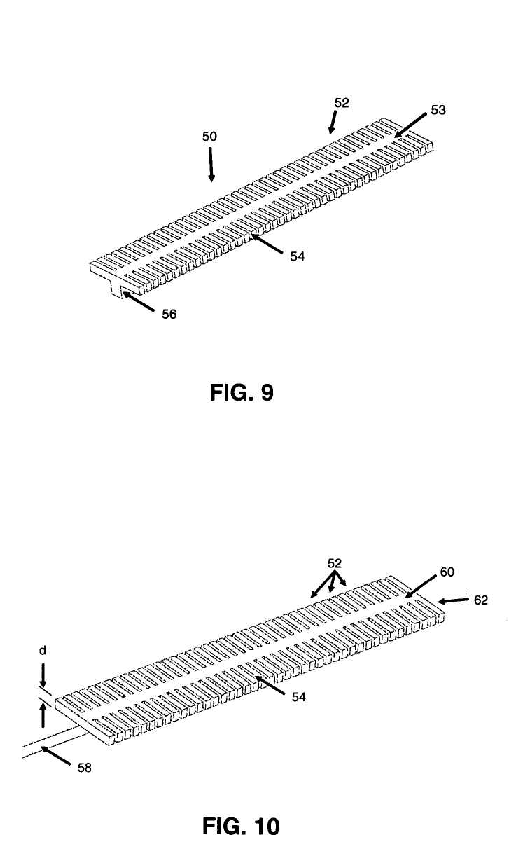

Another alternative embodiment is shown in FIG. 9. In this embodiment 50 a plurality of micro-fins 52 are configured in a plate-like structure portion 53 to form a plurality of micro-channels 54 that extend perpendicularly to a heat conducting apparatus in the form of a rectangular rib 56.

FIG. 10 shows a similar concept, but with a heat pipe 58 joined to a rib portion 60 of the same thickness as the depth “d” of the fins 52. The heat pipe 58 is used in place of the rectangular rib 56 of FIG. 9 to deliver heat to the fins 52, formed in a plate-like structure 62. Other possible micro-fin and micro-channel geometries include cylindrically shaped fins/channels or irregular shaped fins/channels such as those exhibited by metal foam materials.

The heat sink of the present invention is ideally suited for mobile electronics cooling applications. In these cases size and weight are critical. Of particular importance in these applications is the dimension of the heat sink perpendicular to a heat source surface. Because portable devices need to be thin, the low profile heat sink of the present invention is viewed as advantageous.

It should be noted that the heat sink of the present invention can work alone or in conjunction with a fan or blower. Although not shown in the above figures, the heat sink can be designed to work with an axial fan directly attached to the plate and either blowing or sucking gas. The heat sink can also be designed for use with a remote fan or blower, provided that proper ducting is used to force air through the heat sink. If an axial fan is used, the arrangement of micro-channels can be designed specifically for use therewith. For example, the micro-channels can be located exclusively in the annulus opposite of the fan blades. This eliminates dead spots in the flow and allows the fan to operate at peak performance.

The heat sink also lends itself to being able to work with pumps integrated into the micro-channels. The short micro-channel geometry is advantageous for this type of pumping application.

Although the present invention has been particularly described with reference to the preferred embodiments thereof, it should be readily apparent to those of ordinary skill in the art that changes and modifications in the form and details may be made without departing from the spirit and scope of the invention. It is intended that the appended claims encompass such changes and modifications.

What is claimed is:

1. A heat sink comprising:
(a) an arrangement of micro-fins spaced apart to form micro-channels between pairs of micro-fins, wherein each micro-channel is open on a top and bottom of said arrangement for passage of a gas, and has a depth which is defined by a thickness of said arrangement; and
(b) conductive apparatus for conducting heat energy from a heat source to said micro-fins.

2. A heat sink as recited in claim 1 wherein said conductive apparatus includes a post having a proximal end for contacting a heat source, and wherein said arrangement is spaced apart from said proximal end by an offset.

3. A heat sink as recited in claim 2 wherein said arrangement is positioned radially outward from said post in a plane substantially parallel to and spaced apart from a plane of said proximal end of said post.

4. A heat sink as recited in claim 3 wherein said micro-fins have a longest dimension, noted herein as a length, and wherein said length extends in a radial direction from a center line of said post.

5. A heat sink as recited in claim 3 wherein said conductive apparatus includes at least one rib extending from said post.

6. A heat sink as recited in claim 5 wherein said micro-fins have a longest dimension, noted herein as a length, and wherein one end of said length connects to one rib, and an opposite end connects to another rib.

7. A heat sink as recited in claim 6 wherein said length of said micro-fins lies in an arc of a circle with a center coincident with a center of said post.

8. A heat sink as recited in claim 6 wherein a rib includes a heat pipe.

9. A heat sink as recited in claim 2 wherein said proximal end lies in a plane spaced apart from a plane defined by a bottom side of said arrangement, providing an offset space between said proximal end and said bottom side of said arrangement.

10. A heat sink as recited in claim 9 wherein said offset space provides a passage for a gas to flow from and to a bottom opening of said microchannels.

11. A heat sink as recited in claim 3 wherein said micro-fins have a longest dimension, defined herein as a length, and wherein said length is substantially longer than said depth.

12. A heat sink as recited in claim 11 wherein said depth is in the range of 100 to 10,000 microns.

13. A heat sink as recited in claim 12 wherein said length is in the range of 3 to 50 mm.

14. A heat sink as recited in claim 11 wherein a ratio of said length to said depth is in the range of 0.3 to 500.

15. A heat sink comprising:
(a) a plate with an arrangement of micro-fins spaced apart to form micro-channels between pairs of micro-fins, wherein each micro-channel is open on a top and bottom of the arrangement for passage of a gas; and
(b) a conductive apparatus coupled to the plate which establishes an offset between the plate and a surface containing a heat source,
wherein the offset permits the gas to which heat is transferred by the micro-fins to flow through the micro-channels either through a space between the surface and the arrangement from the bottom to the top of the arrangement or from the top to the bottom of the arrangement and through the space.

16. A heat sink according to claim 15, wherein the arrangement comprises a comb-like structure in which the micro-fins are substantially parallel to each other and extend substantially perpendicular to a center post.

17. A heat sink according to claim 15, wherein the arrangement comprises a set of concentric arcs in which the microfins are substantially concentric with respect to a center of a center post.
